(19) United States
(12) Patent Application Publication
(10) Pub. No.: US 2023/0262910 A1
(43) Pub. Date: Aug. 17, 2023

(54) CONTROL ELEMENT

(71) Applicant: Kesseböhmer Holding KG, Bad Essen (DE)

(72) Inventors: René BARKAU, Ostercappeln (DE); Michael STRUNK, Ostercappeln (DE)

(73) Assignee: Kesseböhmer Holding KG, Bad Essen (DE)

(21) Appl. No.: 18/107,527

(22) Filed: Feb. 9, 2023

(30) Foreign Application Priority Data
Feb. 16, 2022 (DE) 10 2022 201 581.9

(51) Int. Cl. H05K 5/02; A47B 19/06

(52) U.S. Cl. CPC H05K 5/0226; A47B 19/06

(57) ABSTRACT

A control element (2) for operating a driven adjustment of a part of a furniture is provided. The control element (2) comprises a fastening section (6) configured to be fastened to the furniture and a control section (3) comprising an operator interface configured to enable an interaction between the furniture and an operator. The control element (2) comprises an adjustment mechanism configured to connect the control section (3) with the fastening section (6) in a manner swiveling about a swivel axis (A) and which is configured such that a swiveling movement of the control section (3) about the swivel axis (A) with respect to the fastening section (6) can be positively locked in a releasable manner.

### RELATED APPLICATION

This application claims the benefit of priority of Germany Patent Application No. 10 2022 201 581.9 filed on Feb. 16, 2022, the contents of which are incorporated by reference as if fully set forth herein in their entirety.

### FIELD AND BACKGROUND OF THE INVENTION

The invention relates to a control element, in particular, to a control element for operating a driven adjustment of a part of a furniture.

Control elements for operating a driven adjustment of a part of a furniture, in particular, of a tabletop of a height adjustable table, are usually arranged beneath a tabletop at an edge of the tabletop such that a control section with switch elements protrudes laterally from the tabletop.

However, there is the risk that, in particular, during transport of the table, the control section is broken off or damaged.

Due to this reason, it is advisable to remove the control section from the vulnerable area, in particular, during the transport of the table. However, disassembly of the control element is not advisable due to a huge effort.

### SUMMARY OF THE INVENTION

Document DE 603 10 060 T2 discloses folding down of the control section, wherein the control element is provided with a joint by means of which the control section can be folded away out of the vulnerable area. The joint is provided with retaining devices such that the control section can occupy different angular positions with respect to a fastening section of the control element in order to, on the one hand, be able to be folded down and, on the other hand, to set against a sufficient resistance when the switch elements are pressed. These retaining devices are proposed as being protrusions and recesses on a rotatable shaft and on a cylindrical surface in a bearing for the shaft, wherein the protrusions and recesses engage with one another. Alternatively, O-rings made of rubber arranged between the rotating shaft and the cylindrical surface in the bearing for the shaft are used in order to generate friction between the rotating shaft and the cylindrical surface in a defined manner so that the control section can be adjusted smoothly.

Hereby, there is however the problem that a force for folding away the control section must be large enough to provide a sufficient resistance when the switch elements are pressed, however, the control section shall be folded away comfortably so that is hard to find a compromise in view of a comfortable amount of the resistance since each movement is to be executed against a retaining force, it generates chatter and, also, larger wear due to abrasion. When determining the resistance such large that the pressing of the switch elements with a large force is also possible without folding away the control section, there is also the risk that the control element is damaged in the event of a collision when not being folded away.

Therefore, the object underlying the invention is to provide a control element which enables, on the one hand, a sure operation of the switch elements and, on the other hand, a comfortable removing of the control section out of a vulnerable area, whereby damaging of the control element is prevented.

The object is achieved by a control element according to claim 1. Advantageous further developments of the invention are included in the dependent claims.

According to an aspect of the invention, a control element for operating a driven adjustment of a part of a furniture comprises a fastening section configured to be fastened to the furniture, a control section comprising switch elements for the operation, and an adjustment mechanism. The adjustment mechanism is configured to connect the control section to the fastening section in a swiveling manner about a swivel axis and it is configured such that a swiveling movement of the control section with respect to the fastening section about the swivel axis can be positively locked in a releasable manner.

In order to be fastened to the furniture, the fastening section comprises, for example, through-orifices or counterbores for fixing screws or the fastening section can be attached to the furniture, for example, on a lower side of a tabletop by clips.

Due to the fact that the swiveling movement can be positively locked, on the one hand, a sufficiently large resistance when operating the switch elements is ensured so that a sure operation is possible. On the other hand, due to the releasable characteristic of the positive locking, it is possible to swivel the control section with respect to the fastening section without large resistance quasi frictionless so that the control section can be removed comfortably out of the vulnerable area.

According to an advantageous implementation of the control element, the adjustment mechanism comprises a first protrusion and a recess and the adjustment mechanism is configured to engage the first protrusion in the recess by means of a first linear movement in order to lock a swiveling movement of the control section with respect to the fastening section about the swivel axis and to move the first protrusion out of the recess by means of a second linear movement in order to release a locking.

By the locking and the releasing of the locking by means of a linear movement, the operation of the adjustment mechanism is possible in an easy and sure manner and the linear movement can be easily superimposed with the swiveling movement for folding away the control section in order to remove the control section out of the vulnerable area.

In a further advantageous implementation of the control element, it comprises a spring element configured to urge the first protrusion into the recess.

By the spring element, it is avoided that the locking is released accidentally or unintentionally so that the switch element can be pressed without unintentionally folding down the control section.

In a further advantageous implementation of the control element, the adjustment mechanism comprises a swivel bolt and a swivel bearing, wherein the swivel bolt is supported by the swivel bearing in a swiveling manner about the swivel axis and, in order to enable the first and second linear movement in a displaceable manner, in a direction along the swivel axis.

In this implementation, the operation is further simplified since the two movements to unlock and to perform the swiveling movement can be performed at the same point.

According to a further advantageous implementation of the control element, the swivel bolt is fixedly attached to the control section and the swivel bearing is fixedly attached to the fastening section.

By this implementation, the operation is further simplified since the two movements to unlock and perform the swiveling movement can easily initiated at the control section.

Upon a further advantageous implementation of the control element, the swivel bolt is fixedly connected to the first protrusion and the swivel bearing is fixedly connected to the recess.

By this assignment, on the one hand, the swivel bolt having the protrusion and, on the other hand, the housing having the recess can easily be manufactured.

According to another advantageous implementation of the control element, the adjustment mechanism is configured to positively lock the swiveling movement of the control section with respect to the fastening section in an operation position, and the attachment mechanism comprises a second protrusion connected to the swivel bearing and a third protrusion connected to the swivel bolt, wherein the second protrusion and the third protrusion are configured to be resiliently engaged in a further position of the swiveling movement of the control section with respect to the fastening section which is not the operation position.

The operation position is defined as the one position in which the control section occupies a position in which the switch elements protrude from the furniture and they can be operated ergonomically. A position which is not the operation position can be any position in which the control section is, for example, just fold away out of the vulnerable area.

By the resilient engagement of the second protrusion and the third protrusion, the control section can be locked in the further position so that the control section can be prevented from an uncontrolled swinging after the locking in the operation position has been released.

Upon a further advantageous implementation of the control element, the position of the swiveling movement is a rest position in which the control section is folded against the furniture.

By occupying this rest position, it is ensured as possible that the control section is in a secured area.

In a further advantageous implementation of the control element, the second protrusion comprises a resilient tongue via which the second protrusion is connected to the swivel bearing.

By the provision of the resilient tongue for the third protrusion, on the one hand, a simple engagement of the second and third protrusions is possible, wherein, on the other hand, a sufficient large force can be easily provided for a sure maintaining of the further position of the swiveling movement.

According to a further advantageous implementation of the control element, the adjustment mechanism comprises a first protrusion and a recess, the adjustment mechanism is configured to engage the first protrusion in the recess in order to lock the swiveling movement, and the adjustment mechanism comprises a swivel bolt and a swivel bearing. The swivel bolt is supported in a swiveling manner about the swivel axis by the swivel bearing, the swivel bolt is fixedly connected to the control section and to the first protrusion, and the swivel bearing is fixedly connected to the recess. The swivel bolt comprises a cross-section which is elastically deformable in a section in the area of the first protrusion so that the swivel bolt is configured such that a position of the first protrusion with respect to the control section can elastically be changed such that the first protrusion can emerge out of the recess.

By this implementation of the adjustment mechanism, the position of the first protrusion with respect to the control section can elastically change when the swiveling movement of the swivel bolt is positively locked and when an excessive force on the control section occurs so that, upon a lower force, initially a yielding of the control section is possible and, upon a higher force, emerging of the first protrusion out of the recess is possible, wherein, by the elastic variability of the position of the first protrusion with respect to the control section, damage of the adjustment mechanism or of the control elements can be prevented.

In a further advantageous implementation of the control element, the cross-section of the swivel bolt is open in the at least one section.

Due to the open cross-section, it is easily possible to constructively determine an elastic variability of the position of the first protrusion with respect to the control section.

Upon a further advantageous implementation of the control element, the adjustment mechanism comprises a first protrusion and a recess, the adjustment mechanism is configured to engage the first protrusion in the recess in order to lock the swiveling movement, and a wall element of the recess at least on one side of the recess is designed to be elastically deformable so that the wall element is configured such that, in the event of a force by the first protrusion on the wall element, it elastically evades such that the first protrusion can emerge out of the recess.

By the elastic deformability of the wall on the at least one side, it is possible that, upon a low force, initially, a yielding of the control section is possible and, upon a higher force, emerging of the first protrusion out of the recess is possible, wherein, by the elastic deformability of the wall on the at least one side, damage of the adjustment mechanism or of the control element can be prevented.

According to a further advantageous implementation of the control element, the wall element of the recess at least on the one side comprises a section in a predetermined distance from the recess having a reduced wall thickness with respect to a wall thickness directly at the recess.

By the reduction of the walls thickness, the elastic deformability of the wall can constructively be determined easily.

In a further advantageous implementation of the control element, the first protrusion comprises a first wall facing the recess and the recess comprises a second wall facing the first protrusion. The first wall has a first wall section and the second wall has a second wall section, wherein the adjustment mechanism is configured such that the first wall section and the second wall section contact one another when a force is applied on the control section. The first wall, in the area of the first wall section, and/or the second wall, in the area of the second wall section, respectively have a shape configured to support an elastic change of the position of the first protrusion with respect to the control section and/or an elastic evasion of the wall element out of the recess.

By the determination of the shape of at least one of the wall sections, the elastic change of the position of the first protrusion with respect to the control section and/or the elastic evasion of the wall of the recess is supported such that these safety functions can reliably be performed.

In a further advantageous implementation of the control element, the shape respectively comprises a surface which is inclined in a direction away from the swivel axis, and a first normal vector onto the surface of the shape of the first wall section in direction of the surface is inclined such that it faces the swivel axis and a second normal vector in direction away from the surface is inclined from the surface of the shape of the second wall section so as to face the swivel axis.

### BRIEF DESCRIPTION OF THE SEVERAL VIEWS OF THE DRAWINGS

Subsequently, the invention is elucidated by means of embodiments referring to the attached drawings.

In particular,

FIG. 1a shows an isometric view of a table with a control element having a control section folded into an operation position;

FIG. 1b shows an isometric view of the table with the control element having the control section folded into a rest position;

FIGS. 2a-c show the control element having different swivel states of the control section;

FIG. 3 shows an isometric view of the control element;

FIGS. 4a-c show simplified plan views onto the control element in different locking states;

FIG. 5a and FIG. 5b show simplified side views of the control element having the swivel states of the control section shown in FIG. 2a and FIG. 2b;

FIGS. 6a-c show simplified lateral sectional views of the control element having different swivel states of the control section;

FIG. 7a and FIG. 7b show a first overload clutch of an adjustment mechanism;

FIG. 8a and FIG. 8b show a second overload clutch of the adjustment mechanism; and

FIG. 9 shows an enlarged section of the control element having the second overload clutch.

### DESCRIPTION OF SPECIFIC EMBODIMENTS OF THE INVENTION

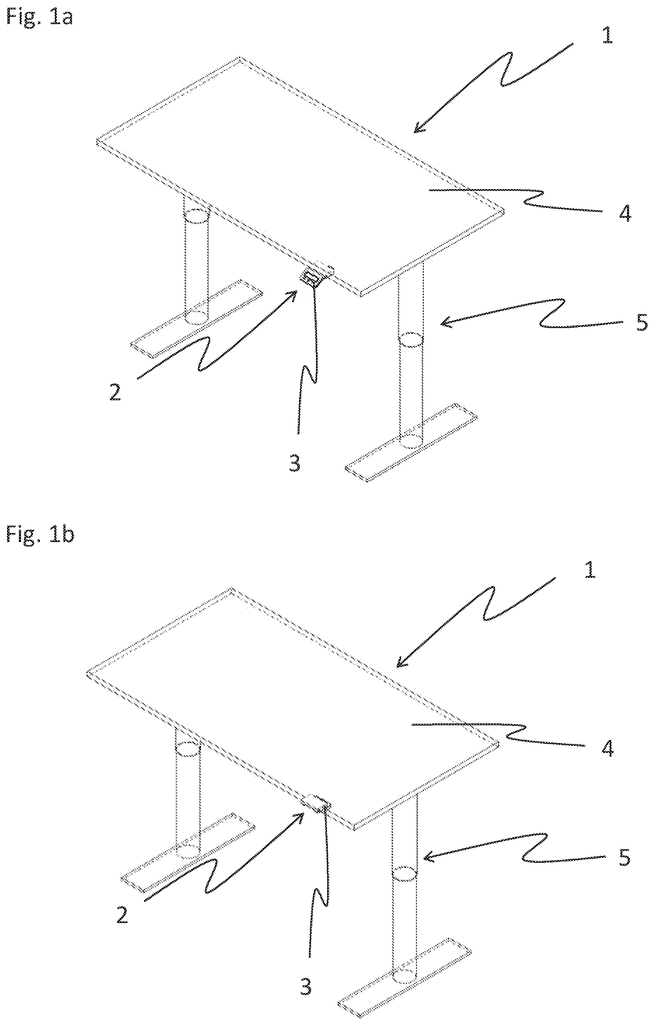

FIG. 1a shows an isometric view of a height adjustable table 1, as an embodiment of a furniture, having a control element 2, a control section 3 of which is folded into an operation position, and FIG. 1b shows an isometric view of the table 1 having the control element 2, wherein the control section 3 is folded into a rest position.

The table 1 comprises a height adjustable tabletop 4 as a part of the table 1 provided with a driven adjustment. Further, the table 1 comprises a table frame 5 provided with telescopic columns in order to adjust the height the tabletop 4 in a driven manner. Thereto, the telescopic columns comprise linear drives (not shown) which are controlled by means of the control element 2. The control element 2 is attached beneath the tabletop 4 such that the control element 2 having the control section 3 swiveled into the rest position is completely covered by the tabletop 4 without protruding from an edge of the tabletop 4. In particular, the rest position is a position in which the control section 3 is completely folded against the furniture, which means that the control section 3 has a smallest possible distance from the surface of the table 1 to which surface the control element 2 is attached. In alternative embodiments, the furniture is not implemented as the table 1 but as another furniture having a driven part, for example, doors of a wardrobe.

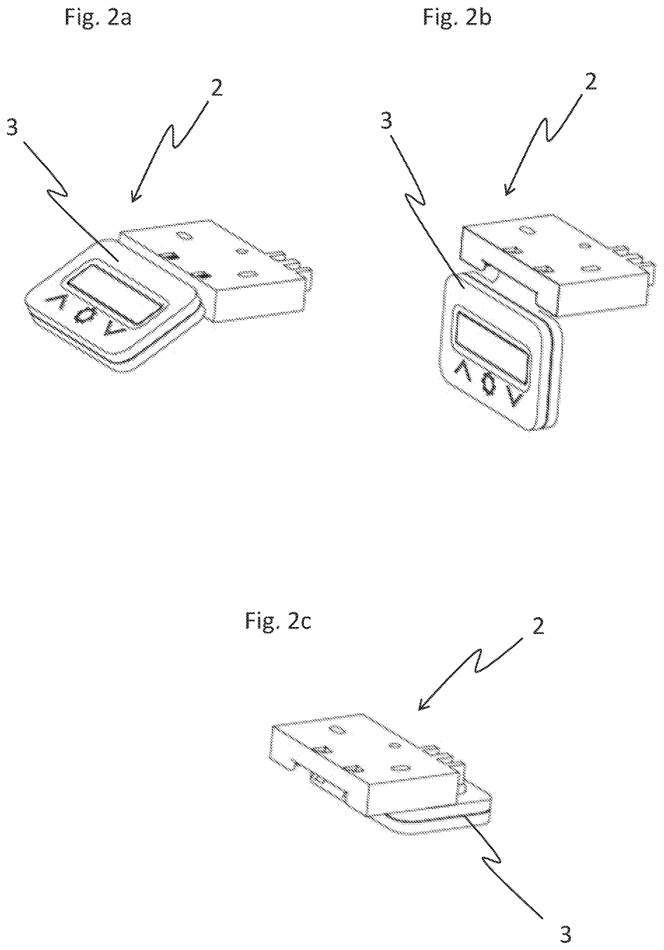

FIGS. 2a-2c show the control element 2 having different swivel states of the control section 3. In particular, FIG. 2a shows the control section 3 in the operation position, FIG. 2b shows the control section 3 in a position in which it is swiveled out of the operation position and, caused by the gravity, it hangs downwards, and FIG. 2c shows the control section 3 in the rest position.

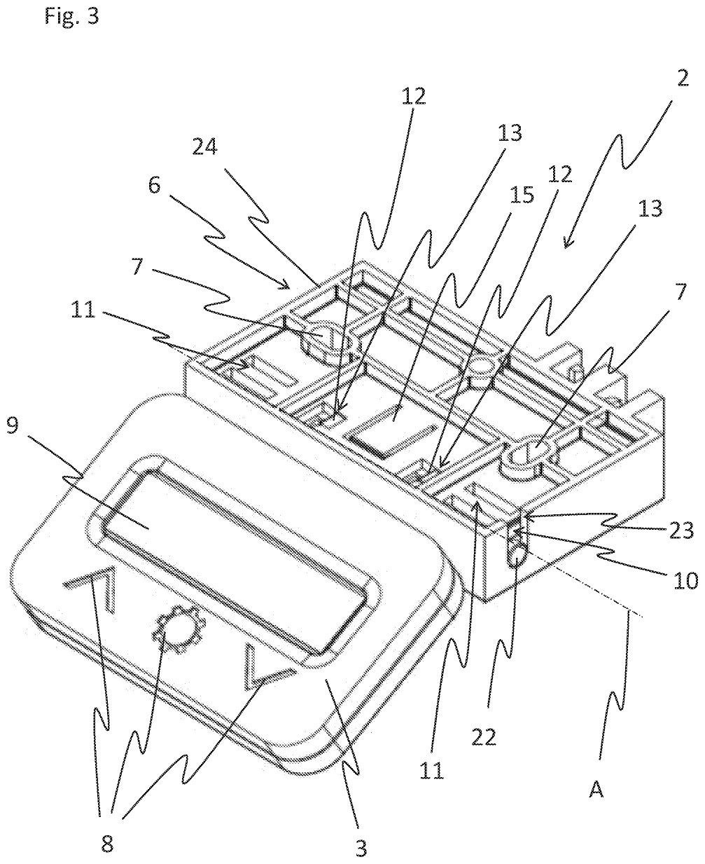

FIG. 3 shows an isometric view of the control element 2. The control element 2 comprises the control section 3 and a fastening section 6. Further, the control element 2 comprises an adjustment mechanism configured to connect the control section 3 to the fastening section 6 in a swiveling manner about a swivel axis A and to positively lock a swiveling movement of the control section 3 with respect to the fastening section 6 about the swivel axis A in a releasable manner.

The fastening section 6 is configured to be fastened to the table 1, in particular, to the tabletop 4. Thereto, the fastening section 6 comprises elongated holes as through orifices 7 by means of which the fastening section 6 is screwed to the tabletop 4. In alternative embodiments, the fastening section 6 can also be fastened to the tabletop 4 by means of, for example, clips or similar fastening elements, or it can be fastened to another part of the table 1.

The control section 3 comprises an operator interface enabling an interaction between the table 1 and an operator, in particular, switch elements 8 for controlling the adjustment of the height adjustable tabletop 4, as well as an optional display field 9. The operator interface comprises the switch elements 8 as being tactile switch elements, however, it can alternatively also comprise a touch display, a microphone, or a device for gesture recognition.

Further, the operator interface optionally comprises an output element. This output element is configured to output a feedback to the operation, for example, via the display field 9, or acoustically via a feedback tone or a feedback announcement.

The adjustment mechanism comprises a swivel bolt 10 and two swivel bearings 11, wherein the swivel bolt 10 is supported by the swivel bearings 11 in a swiveling manner about the swivel axis A and, in a direction along the swivel axis A, it is supported in a displaceable manner in order to enable a linear movement. The swivel bolt 10 is connected integrally to the control section 3 and the swivel bearings 11 are integrally connected to the fastening section 6. In alternative embodiments, the swivel bolt 10 is connected to the control section 3 not integrally, however, fixedly, and/or the swivel bearings 11 are not integrally attached to the fastening section 6, however, fixedly. In further alternative embodiments, the swivel bolt 10 is attached to the fastening section 6 and the swivel bearings 11 are attached to the control section 3 and/or another number of swivel bearings 11, namely, only one or more than two, are provided.

The adjusting mechanism further comprises two first protrusions 12 as well as two recesses 13. The swivel bolt 10 is fixedly connected to the first protrusions 12 and the swivel bearing 11 is fixedly connected to the recesses 13. The swivel bolt 10 comprises the protrusions 12 in an integrally connected manner and the recesses 13 are connected to the swivel bearing 11 via a housing 24 of the fastening section 6. In alternative embodiments, not two protrusions 12 and not two recesses 13 are respectively provided but another suitable number is provided. Moreover, in further alternative embodiments, the swivel bolt 10 is not connected to the first protrusions 12 but it comprises the recesses, wherein, then, the swivel bearing 11 is connected to the protrusions.

The swivel bolt 10 comprises an axial cylindrical protrusion 22 and the housing 24 of the fastening section 6 comprises a recess 23 in a wall. The recess 23 extends from the upper rim of the wall of the housing 24 to the area where the swivel bolt 10 is arranged in the housing 24. The cylindrical protrusion 22 is attached on a front side of the swivel bolt 10 such that it is arranged eccentrically with respect to the swivel bolt 10, therefore, it is not located in the center of the swivel bolt 10 in the swivel axis A. The cylindrical protrusion 22 and the recess 23 are formed such that the cylindrical protrusion 22 is accommodated in the recess 23 when the control section 3 is located in the operation position. In alternative embodiments, the cylindrical protrusion 22 is not actually cylindrical but it has another suitable cross-section, for example, oval, and/or the recess 23 has another shape and/or it is not arranged in the wall of the housing 24 but at another suitable place of the housing 24.

Moreover, in FIG. 3, a tongue 15 can be seen, the function of which is elucidated later.

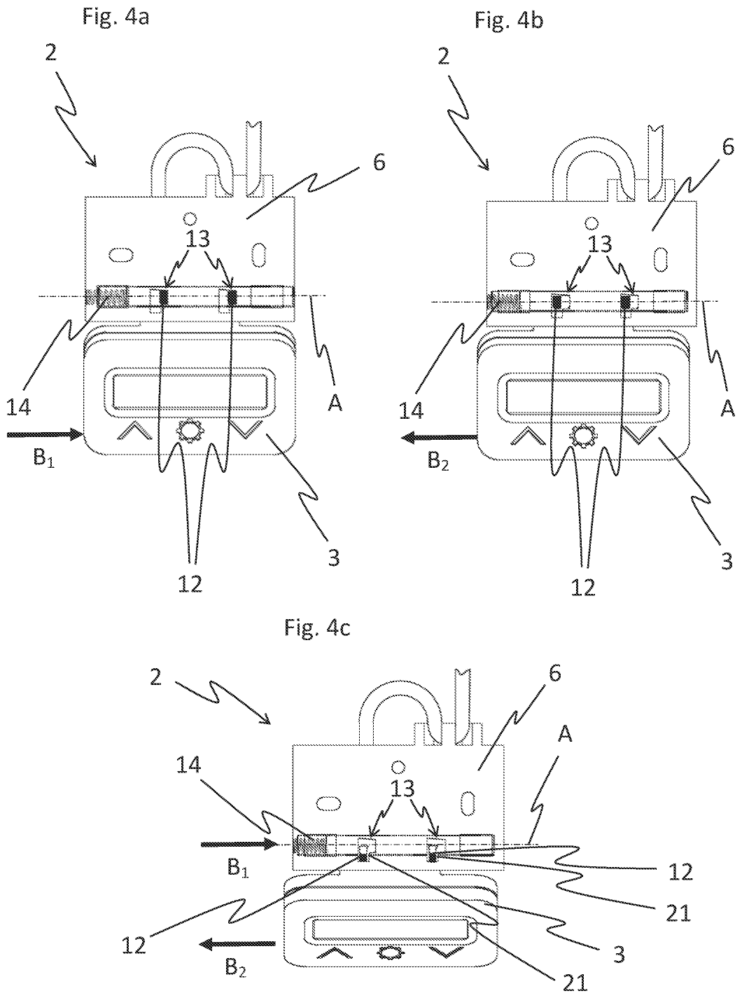

FIG. 4a-FIG. 4c show simplified plan views onto the control element 3 in different locking states.

FIG. 4a shows a state in which the first protrusions 12, respectively illustrated by a black filled rectangle, are engaged in the recesses 13 in order to lock a swiveling movement of the control section 3 with respect to the fastening section 6 about the swivel axis A. This engagement is performed by means of a first linear movement B₁ of the first protrusions 12 relatively to the recesses 13 along the swivel axis A.

The control element 2 comprises a coil spring as a spring element 14 configured to urge the first protrusions 12 into the recesses 13. Thereto, on its one side, the spring element 14 supports against the housing 24 of the fastening section 6 and, on its other side, it supports against the swivel bolt 10. In alternative embodiments, for example, an elastic rubber element or a leaf spring is provided as the spring element 14, wherein it is essential that the spring element 14 is configured to urge the first protrusions 12 into the recesses 13. In further alternative embodiments in which the recesses are attached to the swivel bolt, the recesses 13 are urged by the spring element 14 such that the first protrusions 12 engage with the recesses 13.

FIG. 4b shows a state in which the first protrusions 12 are located out of the recesses 13 by means of a second linear movement B₂ along the swivel axis A in order to release the locking of the swiveling movement of the control section 3 with respect to the fastening section 6 about the swivel axis A. Since the first protrusions 12 are connected to the control section 3 via the swivel bolt and the recesses 13 are connected to the housing 24 of the fastening section 6, the swiveling movement can be locked or the locking can be released by a movement of the control section 3 relatively to the fastening section 6, therefore, to the tabletop 4.

FIG. 4c shows a state in which the first protrusions 12 have been coming out of engagement with the recesses 13 and, additionally, the control section 3 has been folded downwards from the operation position.

The housing 24 comprises support walls 21 (FIG. 4c), against which the first protrusions 12 support in direction of the swivel axis A when, after the first protrusions 12 have been moved out of the recesses 13 from the state shown in FIG. 4a into the state shown in FIG. 4b by the second linear movement B₂ of the control section 3, the control section 3 is folded downwards in the direction downwards into the state shown in FIG. 4c and the control section 3 and, therefore, the first protrusions 12, are urged in direction of the linear movement B₁. For reasons of clarity, in FIG. 4c, the first protrusions 12 are illustrated at a distance from the support walls 21, however, by the linear movement B₁, they abut to the support walls 21 so that the support walls 21 form an axial guide for the swivel bolt 10.

The support walls 21 extend in a plane perpendicular to the swivel axis A and, in direction of the swivel axis A, adjacent to the recesses 13. In alternative embodiments, the support walls 21 extend in a plane which includes a non-square angle, namely, which is another angle than a square angle, with the swivel axis A or the support walls 21 extend along the swivel axis A in the form of a section of a turn of a thread such that, upon folding upward the control section 3, the first protrusion 12 abutting on the support wall 21 moves in direction of the second linear movement B₂ into the operation position. In further alternative embodiments, only one support wall 21 is provided or the support walls 21 are omitted.

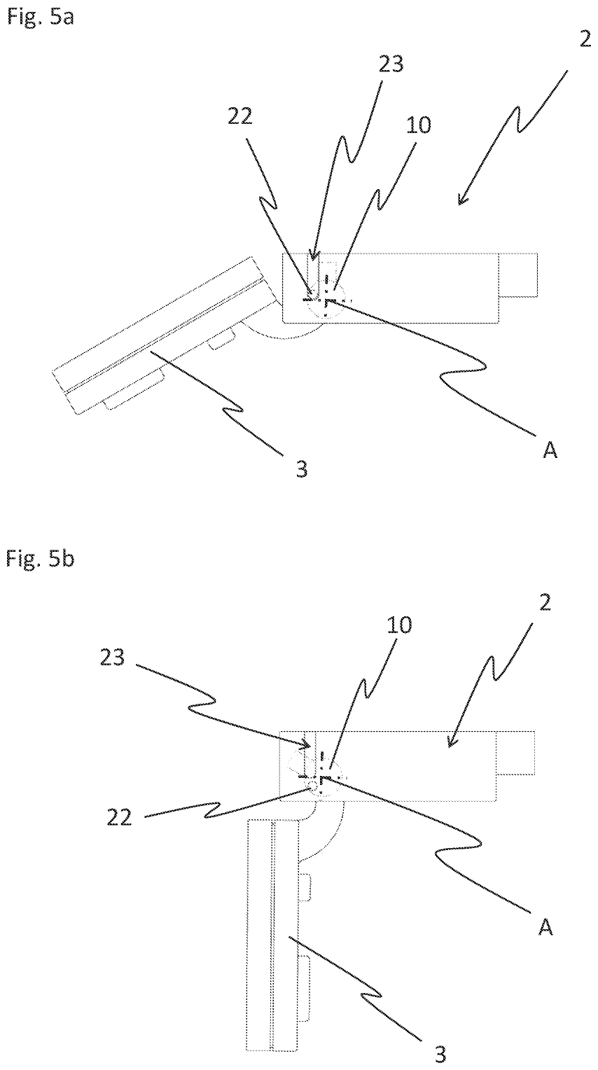

FIG. 5a and FIG. 5b show a simplified side view of the control element 2 having the swivel states of the control section 3 shown in FIG. 2a and FIG. 2b.

In FIG. 5a, the swivel state in which the control section 3 is located in the operation position is shown, and in FIG. 5b, the state in which the control section 3 is in a position in which it is swiveled out of the operation position and, due to the gravity, it hangs downwards, is shown.

As already can be seen in FIG. 3, in the state of the control section 3 in the operation position, the cylindrical protrusion 22 is accommodated in the recess 23.

In FIG. 5b, it can be seen that, in the state where the control section 3 is not in the operation position, the cylindrical protrusion 22 is not accommodated in the recess 23.

Starting from the state shown in FIG. 5a in which the control section 3 is locked in the operation position, the cylindrical protrusion 22 moves axially out of the recess 23 due to the second linear movement B₂. Thus, on the one hand, the first protrusions 12 are no longer engaged with the recesses 13 and, on the other hand, also, the cylindrical protrusion 22 is no longer accommodated in the recess 23, therefore, it is also no longer engaged with the recess 23.

When folding downwards the control section 3 out of the operation position, the cylindrical protrusion 22 arrives in an area of the wall of the housing 24 in which the recess 23 is not provided. A length of the cylindrical protrusion 22 and a necessary amount of the second linear movement B₂ so that the first protrusions 12 comes out of the recesses 13 are attuned such that the cylindrical protrusion 22 abuts on an inner side of the wall of the housing 24 when the swivel bolt 12 is moved thus far in direction of the second linear movement B₂ that the first protrusions 12 are no longer engaged with the recesses 13. When swiveling the control section 3 about the swivel axis A, the cylindrical protrusion 22 then slides along the inner side of the wall so that the swivel bolt 10 cannot move in the direction of the first linear movement B₁ when the control section 3 is not swiveled into the operation position in which the first protrusions 12 can be engaged with the recesses 13 and the cylindrical protrusion 22 can be engaged with the recess 23.

Therefore, the combination of the cylindrical protrusion 22 and the recess 23 can also fulfill the function of the support walls 21, namely the axial guiding of the swivel bolt 10 when the first protrusions 12 are not engaged with the recesses 13. In alternative embodiments, the cylindrical protrusion 22 and the recess 23 are not provided.

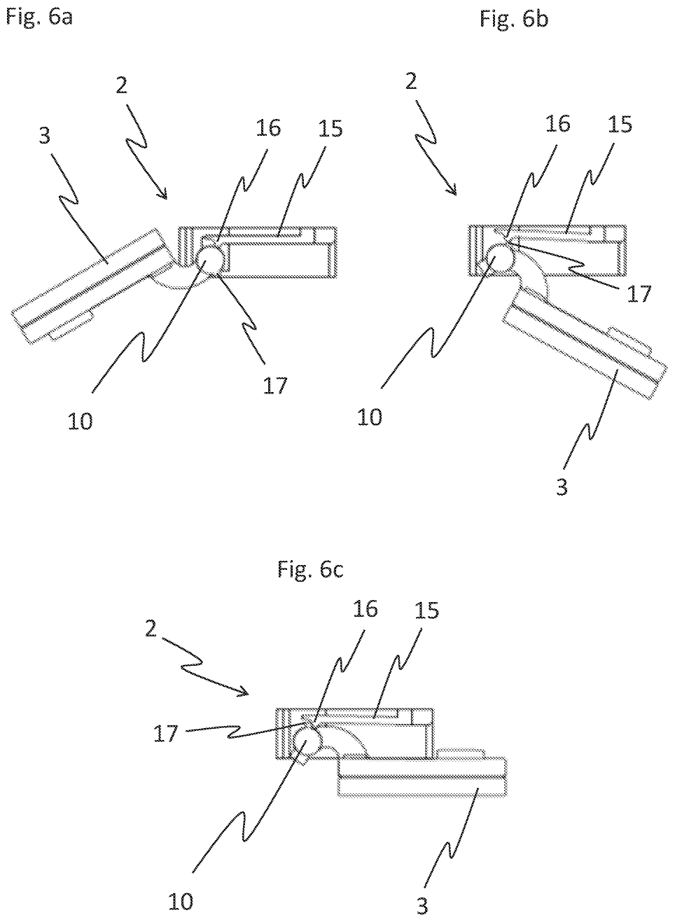

FIG. 6a-c show simplified sectional views of the control element 2 having different swivel states of the control section 3.

The adjustment mechanism of the control element 2 comprises a second protrusion 16 attached to the tongue 15 by means of which the second protrusion 16 is connected to the swivel bearing 11 (FIG. 3). Further, the adjustment mechanism comprises a third protrusion 17 which is fixedly connected to the swivel bolt 10.

In FIG. 6a, the control element 2 is shown in the state in which the control section 3 is in the operation position and this swivel position is locked. Thereby, it can be seen that the third protrusion 17 is not engaged with the second protrusion 16.

In FIG. 6b, the control element 2 is shown in a state in which the swiveling movement of the control section 3 is no longer locked by the first protrusions 12 and the recesses 13 (FIG. 3) but the control section 3 is swiveled in direction towards the rest position. In the shown position, the third protrusion 17 pushes the second protrusion 16 against the force of the resilient tongue 15 out of its original position. However, the second protrusion 16 and the third protrusion 17 are not yet engaged so that the control section 2 can be swiveled back in direction towards the operation position without large effort.

FIG. 6c shows a state in which the second protrusion 16 and the third protrusion 17 are engaged with one another in order to retain the control section 3 in its rest position. When swiveling the control section 3 into its rest position, the second protrusion 16 is pushed away out of its original position by the third protrusion 17 which is enabled by a springy effect of the resilient tongue 15. When the control section 3 is then swiveled into its rest position, the second protrusion 16 springs back again into its original position and the second protrusion 16 and the third protrusion 17 engage with one another in order to retain the control section 3 in a springy manner in its rest position. In alternative embodiments, the second protrusion 16 is not arranged on the resilient tongue but it is supported in a springy manner in another way so that it is able to be resiliently pushed away by the third protrusion 17 and, subsequently, to be engaged with the third protrusion 17 in a springy manner in order to retain the control section 3 in its rest position.

The characteristic that the second protrusion 16 and the third protrusion 17 are engaged in a springy manner means that either, due to its springy support, the second protrusion 16 can be pushed away by the third protrusion 17 out of its original position or, due to its springy support, the third protrusion 17 can be pushed away out of its original position by the second protrusion 16 and, then, it respectively springs back. In further alternative embodiments, the third protrusion 17 is connected to the swivel bolt 10 such that the control section 3 is not retained in its rest position but the control section 3 is retained in another position which, nevertheless, is not the operation position. Further, it is alternatively possible that several second protrusions 16 or several third protrusions 17 are provided so that the control section 3 can be retained in several swivel positions.

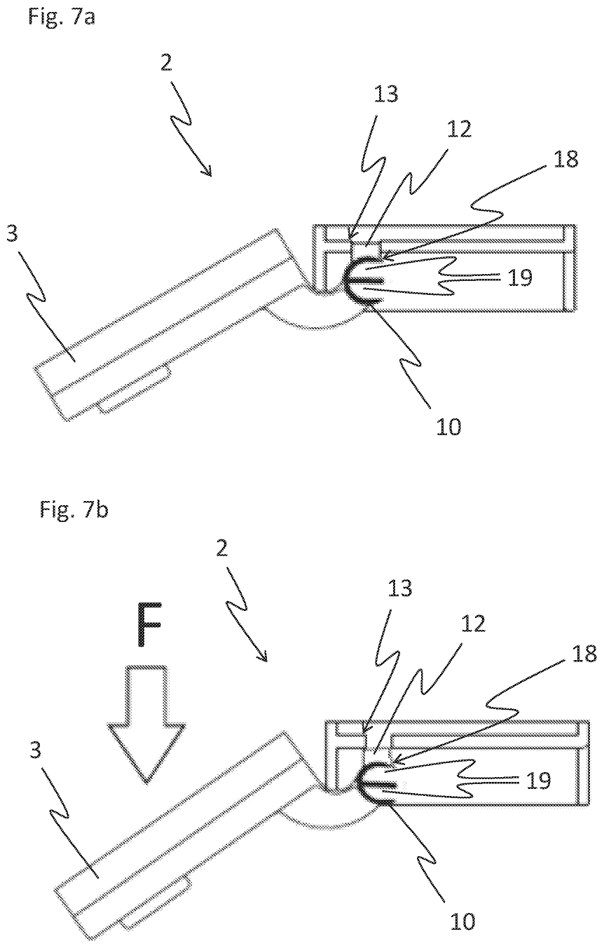

FIG. 7a and FIG. 7b show a first overload clutch of the adjustment mechanism.

As already described above, the swivel bolt 10 is fixedly connected to the control section 3 and to the first protrusion 12 and it is supported in a swiveling manner about the swivel axis A (FIG. 3) via the swivel bearing 11 (FIG. 3).

The swivel bolt 10 comprises a cross-section 18 which is elastically deformable in a section in the area of the first protrusion 12. Thereby, the swivel bolt 10 is configured such that a position of the first protrusion 12 with respect to the control section 3 can be changed elastically such that the first protrusion 12 can emerge out of the recess 13. The cross-section 18 is open in this section. This means that the circumference of the swivel bolt 10 is not continuously closed in this section and that the cross-section comprises two cavities 19 so that the circumference of the swivel bolt 10 is elastically deformable in this section. In alternative embodiments, not two cavities 19 are provided but another number of cavities, wherein it is essential that the circumference of the swivel bolt 10 is elastically deformable in this section.

In FIG. 7a, a situation in which the swiveling movement of the control section 3 is positively locked, therefore, the first protrusion 12 engages with the recess 13, and no excessive force is applied to the control section 3 is shown. The circumference of the swivel bolt 10 is therefore not deformed.

FIG. 7b shows a situation in which an excessive force F is applied to the control section 3. This excessive force F to the control section 3 is transmitted to the swivel bolt 10. Since the first protrusion 12 is engaged with the recess 13, the excessive force F supports against the recess 13, wherein the cross-section 18 of the swivel bolt 10 changes. Thereby, the circumference of the swivel bolt 10 is elastically reduced due to the open cross-section 18 so that the first protrusion 12 can move towards the swivel axis A (FIG. 3). Thereby, the position of the first protrusion 12 with respect to the control section 3 elastically changes and the first protrusion 12 can emerge out of the recess 13 in a radial direction with respect to the swivel bolt 10. By the movement of the first protrusion 12 towards the swivel axis A, therefore, by an elastic evasion of the first protrusion 12, damage of the adjustment mechanism is prevented when the excessive force F occurs.

In alternative embodiments, the swivel bolt 10 does not have an open cross-section 18 but the cross-section is, for example, hollow and it comprises a low wall thickness, or another cross-section is provided. Thereby, it is always essential that the position of the first protrusion 12 with respect to the control section 3 can elastically change. In further alternative embodiments, no such overload clutch is provided.

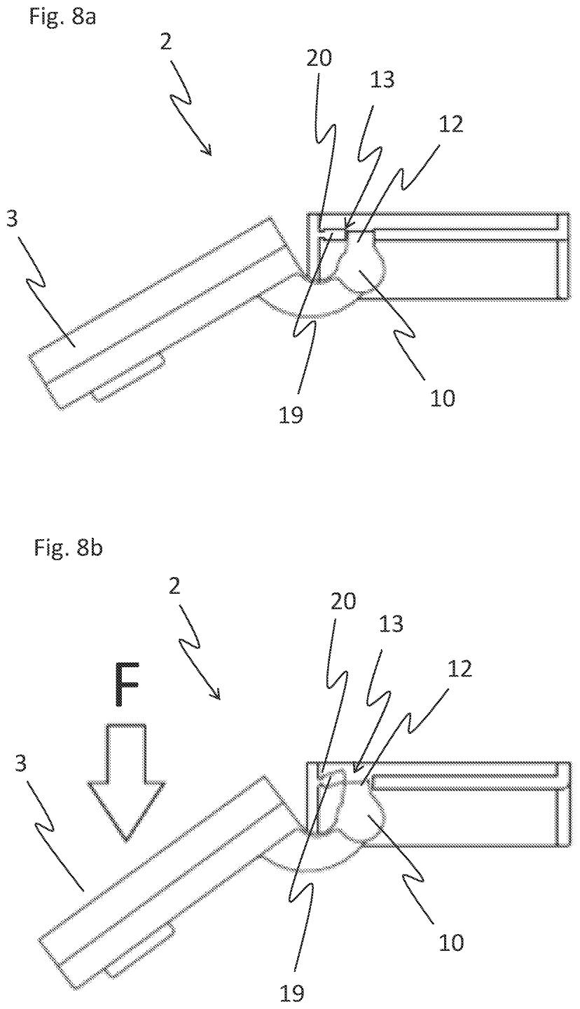

FIG. 8a and FIG. 8b show a second overload clutch of the adjustment mechanism.

As already described above, the swivel bolt 10 is fixedly connected to the control section 3 and to the first protrusion 12 and it is supported in a swiveling manner about the swivel axis A (FIG. 3) by the swivel bearing 11 (FIG. 3).

On one side, the recess 13 comprises a wall element 19 which is designed to be elastically deformable so that the wall element 19 is configured such that, upon an excessive force F on the control section 3 by the first protrusion 12 on the wall element 19, it can elastically evade such that the first protrusion 12 can emerge out of the recess 13. This side of the wall element 19 is particularly the side where, upon a force from above is applied to the control section 3, the first protrusion 12 abuts on the recess 13.

The wall element 19 on the one side of the recess 13 comprises, in a predetermined distance from the recess 13, a section having a reduced wall thickness 20 with respect to a wall thickness directly at the recess 13.

FIG. 8a shows a situation in which the swiveling movement of the control section 3 is positively locked, therefore, the first protrusion 12 is engaged with the recess 13, and no excessive force is applied to the control section 3. The wall of the recess 13 is therefore not deformed.

FIG. 8b shows a situation in which the excessive force F is applied to the control section 3. This excessive force F to the wall section 3 is transmitted to the swivel bolt 10. Since the first protrusion 12 is engaged with the recess 13, the excessive force F supports against the recess 13, wherein the wall element 19 of the recess 13 elastically evades such that the first protrusion 12 can emerge out of the recess 13. By the section with a reduced wall thickness 20, an elastic deformation of the wall element 19 of the recess 13, and, therefore, a yielding in this section, is enabled, wherein, by determining the wall thickness in the section with a reduced wall thickness 20, the excessive force at which the elastic deformation of the wall member 19 becomes large enough to allow the first protrusion 12 emerging out of the recess 13 can be determined.

In alternative embodiments, such a section with a reduced wall thickness is provided on several sides or, instead of the section with a reduced wall thickness 20, a section made of another material having another elasticity than a material of the wall element 19 is provided. In further alternative embodiments, no such overload clutch is provided.

In the embodiments having the cylindrical protrusion 22 and the recess 23, the cylindrical protrusion 22 emerges out of the recess 23 by the excessive force F due to an elastic deformation of the cylindrical protrusion 22 and/or of the wall having the recess 23, wherein the second linear movement B₂ of the swivel bolt 10 occurs. Optionally, the cylindrical protrusion 22 and/or the recess 23 are formed such, for example, having slants, that emerging of the cylindrical protrusion 22 out of the recess 23 is facilitated.

In the embodiments having the support walls 21 (FIG. 4c) respectively extending in the plane enclosing a non-square angle with the swivel axis A or which extend along the swivel axis A in the form of a section of the turn of a thread, the support walls 21 are formed such that, upon folding downward the support section 3 in a plane perpendicular to the swivel axis A due to the excessive force F, the first protrusion 12 comes into a state in which it can abut on the support walls 21 in the direction of the first linear movement B₁.

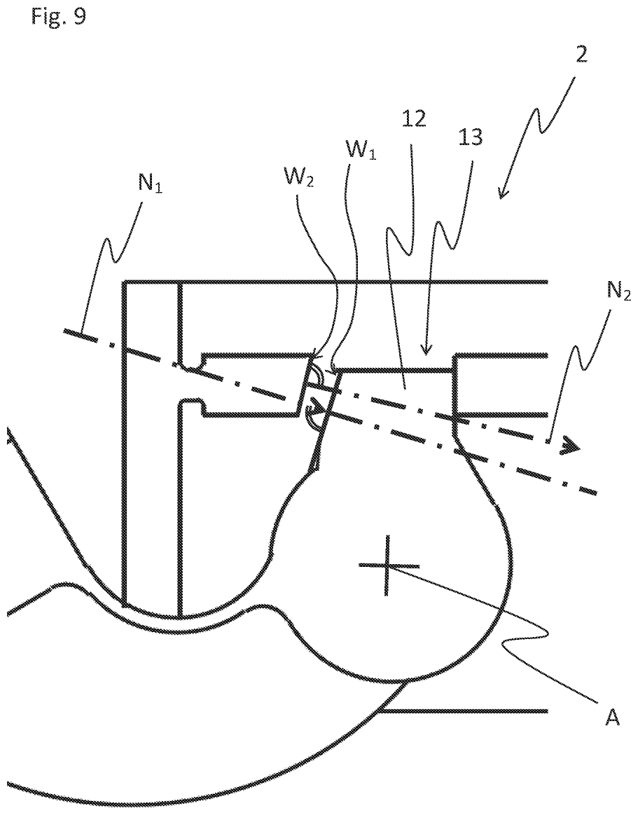

FIG. 9 shows an enlarged section of the control element 2 having the second overload clutch. In particular, an embodiment of the second overload clutch having characteristics which support the elastic evasion of the wall element is shown. The same characteristics can also assist the elastic change of the position of the first protrusion 12 with respect to the control section 3 of the first overload clutch.

In this implementation, the first protrusion 12 comprises a first wall W₁ facing the recess 13 and the recess 13 comprises a second wall W₂ facing the first protrusion 12. The first wall W₁ has a first wall section and the second wall W₂ has a second wall section, wherein the adjustment mechanism is configured such that the first wall section and the second wall section come in contact when a force is applied to the control section 3. In the illustration shown in FIG. 9, this necessary force does not exist so that, for a better present ability, the first wall W₁ and the second wall W₂ are not in contact.

The first wall W₁, in the area of the first wall section, and the second wall W₂, in the area of the second wall section, respectively have a shape configured to assist an elastic change of the position of the first protrusion 12 with respect to the control section 3 in the case of the first overload clutch and to assist an elastic evasion of the wall of the recess in the case of the second overload clutch. The shape is formed as an oblique shape such that a first normal vector N₁ onto a surface of the shape of the first wall section in direction toward the surface is inclined such that it faces the swivel axis A and a second normal vector N₂ of the surface of the shape of the second wall section in a direction away from the surface is inclined so as to face the swivel axis A. Thereby, “facing the swivel axis A” means that the respective normal vector N₁, N₂ coming from the surface of the shape, initially approaches the swivel axis A.

In alternative embodiments, the shape of the wall sections are formed in another shape, for example, curved, however, they also assist the elastic change of the position of the first protrusion 12 with respect to the control section 3 in the first overload clutch and/or the elastic evasion of the wall element 19.

In operation, the tabletop 4 of the table 1 is adjusted in its height by means of the switch elements 8 on the control section 3 of the control element 2, wherein the control section 3 is located in its operation position. Thereby, the control section 3 is located in the locked state reached by swiveling the control section 3 into a predetermined angle position of the operation position and by displacing the control section 3 by means of the first linear movement B₁ so that the first protrusions 12 engage with the recesses 13.

If necessary, for example, when transporting the table 1, the control section 3 of the control element 2 can be brought from its operation position into its rest position in which the control section 3 is completely folded against the tabletop 4 in order to prevent collision with the control section 3.

For folding the control section 3 towards the tabletop 4, the locking of the swiveling movement of the control section 3 with respect to the fastening section 6 about the swivel axis A is released. This is done by the second linear movement B₂ by means of which the first protrusions 12 come out of engagement with the recesses 13. Then, the control section 3 is swiveled into the rest position.

Thereby, if provided, the second protrusion 16 engages with the third protrusion 17 in order to retain the control section 3 in the rest position. While being swiveled into the rest position, the second protrusion 16 is pushed away out of its original position against the springy effect of the resilient tongue 15 by the third protrusions 17 and then springs back.

Four swiveling out of the rest position, the control section 3 is swiveled in the direction of the operation position, wherein a retaining force generated by the spring force of the resilient tongue 15 and the engagement of the second protrusion 16 and the third protrusion 17 is to be overcome. Also in this movement, the second protrusion 16 is pushed away out of its original position by the third protrusion 17 against the springy effect of the resilient tongue 15.

For locking the swiveling movement in the operation position, in the predetermined angle position, the control section 3 is displaced again by the first linear movement B₁ so that the first protrusions 12 enter into the recesses 13.

When the cylindrical protrusion 22 and the recess 23 are provided, as long as the control section 3 is not located in the predetermined angle position for the operation position, the cylindrical protrusion 22 moves along the wall of the housing 24 abutting the wall and, thus, prevents the linear movement B₁. As soon as the control section 3 comes into this predetermined angle position, the cylindrical protrusion 22 enters into the recess 23 by the linear movement B₁ and, therefore, they are engaged.

When the support surfaces 21 are provided, the first protrusions 12 are supported against the support surfaces 21 such that the linear movement B₁ into the recesses 13 is prevented as long as the control section 3 is not in the predetermined angle position for the operation position. As soon as the control section 3 comes into the predetermined angle position for the operation position, the first protrusions 12 are urged into the recesses 13 by the optionally provided spring element 14 in order to lock the control section 3 in the operation position.

If, in the case of the first overload clutch, an excessive force is applied to the control section 3 in the state locked in the operation position, the swivel bolt deforms such that the positions of the first protrusions 12 with respect to the control section 3 change such that the first protrusions 12 can emerge out of the recesses 13. Since this deformation is elastic, the swivel bolt 10 resumes its original shape after the first protections 12 emerge out of the recesses 13. Therefore, by executing the second linear movement B₂ and, after reaching the predetermined angle position of the operation position, the control section 3 can be locked in the operation position again by executing the first linear movement B₁.

In the case of the second overload clutch, if an excessive force is applied to the control section 3 in the state locked in the operation position, the wall element 19 deforms elastically such that it can evade so that the first protrusion 12 can emerge out of the recess 13. Since also this deformation is elastic, the wall element 19 resumes its original shape after the first protrusions 12 emerge out of the recesses 13. Therefore, also here, the control section 3 can again be locked in the operation position by executing the second linear movement B₂ and, after reaching the predetermined angle position of the operation position, by executing the first linear motion B₁.

Due to the respective shape of the wall sections of the first wall W₁ and of the second wall W₂, the respective elastic movement is assisted.

The cylindrical protrusion 22 emerges out of the recess 23 by the elastic deformation of the cylindrical protrusion 22 and/or of a wall of the recess 23 due to the excessive force F, whereby the swivel bolt 10 executes the second linear movement B₂. Thereby, the swiveling movement of the swivel bolt 10 is guided axially such that the first linear movement B₁ cannot be executed until the control section 3 is located in the angle position for the operation position and the cylindrical protrusion 22 can enter into the recess 23 as well as the first protrusions 12 can be engaged with the recesses 13 in order to lock the control section 3 in the operation position.

If the support walls 21 respectively extending in the plane enclosing the non-square angle with the swivel axis or extending along the swivel axis A in the form of the section of the turn of a thread are provided, when the control section 3 is folded downwards in the plane perpendicular to the swivel axis A due to the excessive force, the first protrusions 12 come into the state in which they can abut on the support walls 21. In a subsequent swiveling of the control section 3 in direction towards the operation position, the control section 3 is urged in direction of the second linear movement B₂ by abutting of the first protrusions 12 on the support walls 21 so that the first protrusions 12 can again engage with the recesses 13 and lock the control section 3 when the angle position for the operation position is reached.

Although the present invention has been described with reference to certain features and embodiments, it is apparent that various modifications and combinations thereof may be made thereto without departing from the spirit and scope of the invention. The description and the drawings are accordingly to be considered merely as an illustration of the invention as defined by the appended claims and are intended to cover all modifications, variations, combinations or equivalents falling within the scope of the present invention.

1. Control element for operating a driven adjustment of a part of a furniture, wherein the control element comprises:
a fastening section, configured to be fastened to the furniture,
a control section comprising an operator interface configured to enable an interaction between the furniture and an operator, and
an adjustment mechanism configured to connect the control section with the fastening section in a swiveling manner about a swivel axis, and
configured such that a swiveling movement of the control section with respect to the fastening section about the swivel axis can be positively locked in a releasable manner.

2. Control element according to claim 1, wherein
the adjustment mechanism comprises a first protrusion and a recess, and
the adjustment mechanism is configured to engage the first protrusion in the recess by means of a first linear movement in order to lock a swiveling movement of the control section with respect to the fastening section about the swivel axis, and to move the first protrusion out of the recess by means of a second linear movement) in order to release a locking.

3. Control element according to claim 2, wherein
the control element comprises a spring element configured to urge the first protrusion into the recess.

4. Control element according to claim 2, wherein
the adjustment mechanism comprises a swivel bolt and a swivel bearing, wherein the swivel bolt is supported by the swivel bearing in a swiveling manner about the swivel axis and in a displaceable manner in a direction along the swivel axis in order to enable the first and second linear movement.

5. Control element according to claim 4, wherein the swivel bolt is fixedly attached to the control section and the swivel bearing is fixedly attached to the fastening section.

6. Control element according to claim 4, wherein
the swivel bolt is fixedly connected to the first protrusion, and the swivel bearing is fixedly connected to the recess.

7. Control element according to claim 4, wherein
the adjustment mechanism is configured to positively lock the swiveling movement of the control section with respect to the fastening section in an operation position, and
the adjustment mechanism comprises a second protrusion connected to the swivel bearing and a third protrusion connected to the swivel bolt, wherein the second protrusion and the third protrusion are configured to be resiliently engaged in a further position of the swiveling movement of the control section with respect to the fastening section which is not the operation position.

8. Control element according to claim 7, wherein the
the position of the swiveling movement is a rest position in which the control section is folded against the furniture.

9. Control element according to claim 7, wherein
the second protrusion comprises a resilient tongue via which the second protrusion is connected to the swivel bearing.

10. Control element according to claim 1, wherein
the adjustment mechanism comprises a first protrusion and a recess,
the adjustment mechanism is configured to engage the first protrusion in the recess in order to lock the swiveling movement, and
the adjustment mechanism comprises a swivel bolt and a swivel bearing, wherein
the swivel bolt is supported in a swiveling manner about the swivel axis by the swivel bearing,
the swivel bolt is fixedly connected to the control section and to the first protrusion, and the swivel bearing is fixedly connected to the recess, and
the swivel bolt comprises a cross-section which is elastically deformable in a section in the area of the first protrusion so that the swivel bolt is configured such that a position of the first protrusion with respect to the control section can elastically be changed such that the first protrusion can emerge out of the recess.

11. Control element according to claim 10, wherein
the cross-section of the swivel bolt is open in the at least one section.

12. Control element according to claim 1, wherein
the adjustment mechanism comprises a first protrusion and a recess,
the adjustment mechanism is configured to engage the first protrusion in the recess in order to lock the swivel movement, and
a wall element of the recess at least on one side of the recess is designed to be elastically deformable so that the wall element is configured such that, in the event of a force by the first protrusion on the wall element, it elastically evades such that the first protrusion can emerge out of the recess.

13. Control element according to claim 12, wherein
the wall element of the recess at least on the one side comprises a section having a reduced wall thickness in a predetermined distance from the recess with respect to a wall thickness directly at the recess.

14. Control element according to claim 9, wherein
the first protrusion comprises a first wall facing the recess,
the recess comprises a second wall facing the first protrusion,
the first wall has a first wall section and the second wall has a second wall section, wherein the adjustment mechanism is configured such that the first wall section and the second wall section come into contact to one another when a force is applied on the control section, and
the first wall, in the area of the first wall section, and/or the second wall, in the area of the second wall section, respectively have a shape configured to assist an elastic change of the position of the first protrusion with respect to the control section and/or an elastic evasion of the wall element out of the recess.

15. Control element according to claim 14, wherein
the shape respectively comprises a surface which is inclined in a direction away from the swivel axis, and
a first normal vector onto the surface of the shape of the first wall section in direction of the surface is inclined such as to face the swivel axis, and
a second normal vector from the surface of the shape of the second wall section in direction away from the surface is inclined such as to face the swivel axis.
